(19) United States
(12) Patent Application Publication
(10) Pub. No.: US 2007/0089676 A1
(43) Pub. Date: Apr. 26, 2007

(54) Arrangement for the vapor deposition on substrates

(76) Inventor: Gunter Klemm, Nidda (DE)

Correspondence Address: FULBRIGHT & JAWORSKI, LLP, 666 FIFTH AVE, NEW YORK, NY, 10103-3198, US

(21) Appl. No.: 11/446,445

(22) Filed: Jun. 2, 2006

(30) Foreign Application Priority Data
Oct. 26, 2005 (EP) 050 23 354

(51) Int. Cl. C23C 16/00

(52) U.S. Cl. 118/726

(57) ABSTRACT

The invention relates to an arrangement for the vapor deposition on substrates. It includes a pan as well as a cover with linearly disposed bores. Above this cover is seated a seal-off device, which also includes openings. Through the seal-off device the bores of the cover can be opened or closed, all bores being addressed simultaneously. Through the seal-off device different evaporation rates can be set within an extremely short time.

### BACKGROUND AND SUMMARY OF THE INVENTION

This application claims priority from European Patent Application No. 050 23 354 filed Oct. 26, 2005, incorporated herein by reference in its entirety.

The invention relates to an arrangement for the vapor deposition on substrates.

Synthetic films are often provided with a metal layer under vacuum, for example in order to make them impermeable to gases or electrically conductive. If not all of the areas are to be made conductive, but only certain tracks, those areas which are not to receive a metal layer are provided with strips of oil film. Due to these films, no metal adheres on the lamination. These oil film strips are applied by means of an oil evaporator.

An arrangement is known for producing metal-free strips in the case of film tracks coated in vacuo, in particular for capacitors, in which a vessel filled with oil is provided, which has at least one vapor outlet tube (DE 39 22 187 A1). The outlet nozzle of this vapor outlet tube terminates below the surface level of the oil in the coating chamber in the direct proximity of a substrate to be coated.

Furthermore, a method and an arrangement for the production of metal-free strips in the metal vapor deposition of an insulating material band is known (EP 0 756 020 A1). Herein in the area of the metal-free strips to be produced a covering band is applied, which is coated with oil on one side by means of an oil evaporator. Details of the structure of the oil evaporator are not provided.

In another known arrangement for the production of oil maskings a cylindrical masking roller is provided, into which masking oil is introduced (JP 2001-279425). On the circumference of the masking roller is an opening through which the masking oil is output. A thin lamination with throughbores is located above the roller, with the throughbores overlapping with the opening.

A further arrangement in which a substrate is guided past several linearly disposed nozzles is disclosed in JP 2004-214185. The arrangement described here is comprised of a box-shaped device filled with oil, with the heating system located beneath the arrangement.

The above noted arrangements do not include the capability of dosing the quantity of oil vapor streaming out.

The invention therefore addresses the problem of providing an arrangement for the vapor deposition of oil on substrates, which makes it possible to set the quantity of the oil vapor streaming out.

The problem is resolved according to the present invention.

The invention consequently relates to an arrangement for the vapor deposition on substrates. It includes a pan as well as a cover with linearly disposed bores. Above this cover is seated a seal-off device which also has openings. Through the seal-off device the bores of the cover can be closed or opened, with all bores being addressed simultaneously. Within an extremely short time different evaporation rates can be set through the seal-off device.

The arrangement described in the present invention has the advantage that a significantly better uniformity of the vapor pressure, and therewith of the oil strip precision, over the full working width of the film is attained.

The arrangement includes several bores disposed in a row and the bores can be opened or closed by means of a seal-off device. This seal-off device also includes openings and by actuating the seal-off device, the bores can be opened or closed.

This seal-off device addresses all bores simultaneously such that a uniform opening of all bores is made possible.

It becomes therewith possible to set an evaporation rate of the thermally inert evaporation arrangement within an extremely short time.

One advantage of the invention comprises that the seal-off device can be disposed such that the quantity of vapor streaming out remains constant at all times. Due to this constancy of the vapor quantity, the coating of the substrate becomes also uniform, such that the arrangement is especially well suited for forming strips, patterns as well as areal metal-free zones on metallized synthetic films.

A further advantage of the invention lies therein that the evaporation space during the preparation as well as during the termination of the vapor deposition process can be closed by means of the seal-off device. Leakage of the oil therewith becomes improbable, which also reduces to a minimum the contamination of the environment with oil. The oil loss can thus be drastically reduced. The seal-off device consequently has the capability of assuming an open or a closed position.

With the capability of adjusting the quantity of oil vapor streaming out, the oil quantity can be optimized such that it becomes possible to increase the quality of the metal-free zones with respect to edge precision and residual oil quantities. Precise setting can for example take place thereby that by means of measuring equipment the quantity of discharged oil is determined. If the discharged quantity of oil vapor does not correspond to the nominal value, a signal is conducted to a device via which the seal-off device is actuated such that the quantity of oil vapor is again set to the nominal value.

The arrangement is further conceptualized such that the rising vapor can leave the arrangement only in the upward direction, i.e. toward one side, since it is entirely impermeable to the vapor on all other sides. Thereby that cross flows no longer occur the vapor pressure is nearly equal in all regions of the arrangement, whereby also no flow resistances exist in the space below the nozzles. Due to the shallow structuring of the crucible and of the seal-off device in the form of a slide, the arrangement can assume much smaller dimensions than previously known evaporator units.

The subject matter of the invention is shown in the drawing and will be explained in further detail in the following.

### BRIEF DESCRIPTION OF THE DRAWINGS

FIG. 1 is a perspective view of an arrangement for the vapor deposition on substrates of oil with the substrate guided past.

FIG. 2 is a perspective view of the arrangement according to FIG. 1 without substrate and without a nozzle bar,

FIG. 3 is a segment of a longitudinal section through the arrangement according to FIG. 1 along A-A with a slide in the open position.

### DETAILED DESCRIPTION

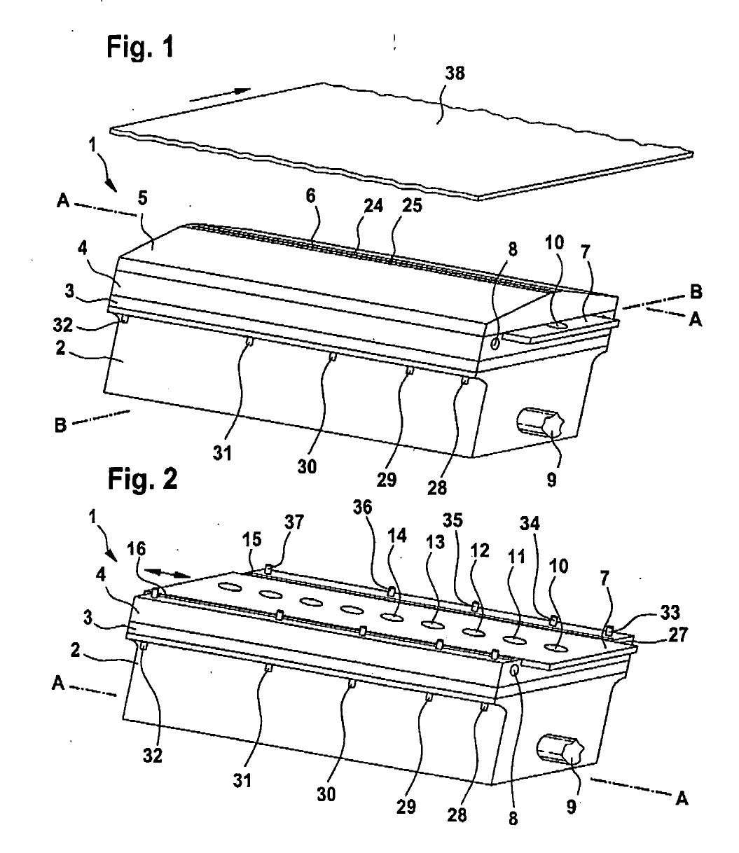

FIG. 4 is a section through the arrangement shown in FIG. 1 along B-B after rotation by 90° in the clockwise direction with the slide in the open position.

FIG. 1 shows a perspective view of an arrangement 1 for the vapor deposition on substrates of materials, for example organic materials, under vacuum. Over the arrangement 1 a laminar substrate 38 is guided along B-B. If the substrate is a synthetic film, it can, as described in JP 2001-279425, be moved over the arrangement 1. To generate sharp-edged strips, the distance between substrate 38 and the arrangement 1 is most often very small.

The arrangement 1 includes an oil pan 2, in which is disposed oil to be evaporated. On this oil pan 2 lies an insulating layer 3, on which a heating plate 4 is disposed. On the heating plate 4 is located a nozzle bar 5, which has a gap 6 on its top edge. Instead of a gap 6, individual nozzles can also be provided. Along line A-A is provided a slide 7 with bores, of which in FIG. 1 only bore 10 is visible. The gap 6 is delimited by two regions 24, 25.

The arrangement 1 comprises furthermore connecting elements 28 to 32, which connect with one another the oil pan 2, the insulating layer 3, the heating plate 4 as well as the nozzle bar 5 resting thereon.

The oil pan 2 includes at least one heating system, which is shown in FIG. 1 as a rod heater 9. This heater 9 is for example a resistance heater, which is preferably operated via an AC voltage source. Through this rod heater 9 the oil in the oil pan 2 is evaporated.

To prevent the condensation of the vapor in the central region of the arrangement 1, the heating plate 4 includes at least one separate rod heater 8.

FIG. 2 shows a perspective view of the arrangement 1 depicted in FIG. 1 without the substrate 38 and without the nozzle bar 5. Again, the slide 7 can be seen, which is disposed in the heating plate 4. As shown here, this slide 7 can assume the form of an elongated plate. The heating plate 4 is in contact on the insulating plate 3 which rests on the oil pan 2, and the insulating plate 3, the heating plate 4 and the oil pan 2 are connected with one another through the connecting elements 28 to 37. The rod heaters 9, 8 and 27 are moreover evident.

The insulating plate 3 serves for the thermal decoupling of oil pan 2 and the plate 4. With the separate heaters, the rod heater 8 and the heater 9 different temperatures can therewith be set in the plate 4 and in the oil pan 2. The insulating plate 3 is comprised of a substantially flexible synthetic material, which serves simultaneously as a sealing material.

The heating plate 4 has in its center along line A-A a recess into which the slide 7 is fitted. This slide 7 has several openings 10 to 14 disposed in a row, which are spaced substantially equidistantly from one another. The slide 7 is displaceable along A-A (see arrow). It must have at least as many openings 10 to 14 as the heating plate 4—not visible in FIG. 2—has bores, the distance of the centers of two openings 10 to 14 corresponding to the distance of the centers of two bores in the heating plate 4. The diameter of the bores of the heating plate 4 corresponds substantially to the diameter of the openings 10 to 14 of the slide 7. Consequently the slide 7 is of a length corresponding to the length of the heating plate 4 plus the distance of the center of two openings 10 to 14. It becomes thereby possible that, for one, the centers of openings 10 to 14 can lie precisely over the centers of the bores and, for another, between the centers of the bores. If they are precisely above the bores, the vapor can escape from the interior of the oil pan 2, however, if they lie between the bores, an escape of the vapor is prevented. It is understood that between these two extreme positions there are possible positions in which a reduced quantity of vapor can escape. It is understood that a greater number of, and also smaller sized, openings 10 to 14 can be provided, than is shown in FIG. 2.

On both sides of the heating plate 4, which extend along A-A, a sealing material 15, 16 is disposed which prevents vapor from escaping from the oil pan 2. This sealing material 15, 16 contains preferably a rubber-type elastic material.

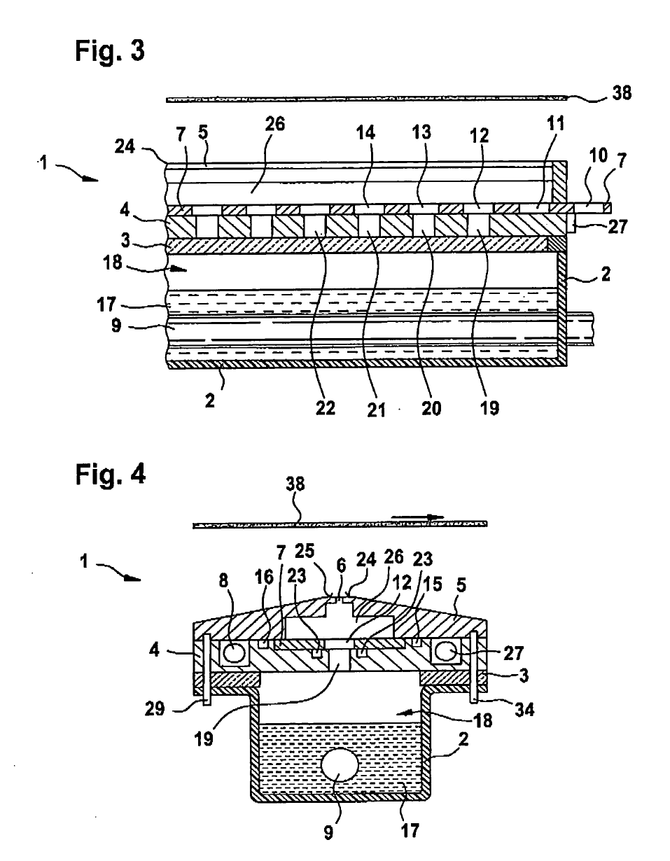

FIG. 3 depicts a segment of a longitudinal section through the arrangement according to FIG. 1 along A-A. In the interior space 18 of the oil pan 2 can be seen the heating rod 9, which is completely encompassed by oil. On the oil pan 2 is located the insulating plate 3, on which the heating plate 4 is disposed. This heating plate 4 includes several bores 19 to 22, out of which the vapor can rise through the openings 10 to 14 of the slide 7 into the interspace 26.

As can be seen in FIG. 3 a portion of the slide 7 with opening 10 lies outside of the oil pan 2. The slide 7 is so disposed on the heating plate 4 that a portion of the openings 12 to 14 of the slide is aligned with the bores 19 to 21 of the heating plate 4. The rising vapor can consequently penetrate out of the arrangement 1 through the bores 19 to 21 and the openings 12 to 14 into the interspace 26 of the nozzle bar 5 and from there through the gap 6. In this way the vapor reaches the substrate 38 which is moved over the arrangement 1.

If the slide 7 is slid further into the arrangement 1 it can be attained that the openings 10 to 12 now only partially lie above bores 19 to 22. The slide 7 in this case acts like a throttle valve, since less vapor can penetrate out of the oil pan 2. If the slide 7 is slid even further into the arrangement 1, the coating process is completely interrupted, since none of the openings still lies over the bores 19 to 22 and it is no longer possible for vapor to escape from the oil pan 2.

FIG. 4 shows a section through the arrangement 1 depicted in FIG. 3 along B-B after rotation about 90° in the clockwise direction. A substrate 38 is moved over and past the arrangement 1. In the interior 18 of the oil pan 2 extends the heating rod 9, which is completely encompassed by oil 17.

On the oil pan 2 lies the insulating plate 3 as well as the heating plate 4 and the nozzle bar 5. All of these elements 2 to 5 are held together with connecting pieces 29, 34, such that they are closely adjoining one another. It is thereby not possible for vapor to escape at the sides of the arrangement 1. Through the heating plate 4 extend the two heating rods 8 and 27. Visible are also the rubber-type elastic material 15, 16 as well as the sealing material 23 which extends parallel to bore 19. This bore 19 is consequently, as are the remaining bores 20, 21, 22, also completely encompassed by sealing material.

On the heating plate 4 rests the slide 7 with opening 12, which lies directly over bore 19. Therewith the rising vapor can reach the interspace 26. In order to attain uniform oil strips specifically in the case of nozzle bars with few nozzles, an equalization of the vapor pressure must be possible without marked flow resistances. Therefore the interspace 26 beneath the nozzles must be as large as possible. The nozzle bar 5 has a gap 6 defined by the two regions 24, 25. Through the gap 6 the vapor can leave the arrangement 1 and reach the substrate 38 moving past it, where it lastly condenses.

The sliding of the slide 7 accomplishes that the opening 12 no longer, or only partially, lies over bore 19.

If it lies only partially over bore 19, a throttle effect is obtained, in contrast, if the opening 12 is no longer over bore 19, no vapor can escape. Consequently the slide 7 acts as a seal-off valve.

Once the coating process has been completed and the arrangement 1 has cooled down, the connecting pieces 29, 34 can be removed and the unit can readily be taken apart and cleaned.

1-14. (canceled)

15. An arrangement for the vapor deposition on substrates, comprising a pan as well as above the pan a cover with linearly disposed bores, wherein above the cover a seal-off device is provided which also includes linearly disposed openings.

16. An arrangement as claimed in claim 15, wherein the seal-off device has at least as many openings as the cover has bores.

17. An arrangement as claimed in claim 15, wherein the seal-off device is movable along one coordinate.

18. An arrangement as claimed in claim 15, wherein the seal-off device has substantially a length which corresponds to the length of the cover.

19. An arrangement as claimed in claim 15, wherein the seal-off device has at least the length of the cover plus a length corresponding to the distance of the center of two bores.

20. An arrangement as claimed in claim 15, wherein the distance between the centers of two adjacent openings of the seal-off device corresponds approximately to the distance between the centers of two adjacent bores of the cover.

21. An arrangement as claimed in claim 15, wherein the seal-off device assumes a position in which the centers of the openings lie precisely above the centers of bores of the cover.

22. An arrangement as claimed in claim 15, wherein the seal-off device assumes a position in which the centers of the openings lie precisely in the center between adjacent bores of the cover.

23. An arrangement as claimed in claim 15, wherein the pan has at least one heater.

24. An arrangement as claimed in claim 15, wherein the cover has at least one heater.

25. An arrangement as claimed in claim 15, wherein between the pan and the cover an insulating plate is provided.

26. An arrangement as claimed in claim 15, wherein above the seal-off device a vapor interspace in a nozzle bar is provided.

27. An arrangement as claimed in claim 26, wherein above the vapor interspace a gap is provided in the nozzle bar.

28. An arrangement as claimed in claim 23, wherein the heater is a rod heater.

29. An arrangement as claimed in claim 24, wherein the heater is a rod heater.
